(19) United States
(12) Patent Application Publication
(10) Pub. No.: US 2026/0293066 A1
(43) Pub. Date: Sep. 24, 2026

(54) HARNESS HEAT DISSIPATION STRUCTURE

(71) Applicant: Yazaki Corporation, Tokyo (JP)

(72) Inventor: Hiroaki ITO, Shizuoka (JP)

(73) Assignee: Yazaki Corporation, Tokyo (JP)

(21) Appl. No.: 19/676,278

(22) Filed: May 13, 2026

Related U.S. Application Data
(63) Continuation of application No. PCT/JP2024/041207, filed on Nov. 21, 2024.

(30) Foreign Application Priority Data
Dec. 18, 2023 (JP) 2023-213084

(51) Int. Cl. H05K 7/20; B60R 16/02

(52) U.S. Cl. CPC H05K 7/20854; B60R 16/0215

(57) ABSTRACT

A harness heat dissipation structure includes a wire harness that is routed on a vehicle body of a vehicle, and a pressing member that presses the wire harness against the vehicle body. The wire harness includes an electric wire including a conductor core wire having electric conductivity and a covering insulator covering the conductor core wire, the electric wire includes a flat portion having a flat cross-sectional shape in a direction orthogonal to a routing direction of the wire harness, and the vehicle body includes a thick portion that is formed thicker than surrounding portions at a location where the pressing member is attached and where the flat portion of the electric wire of the wire harness is pressed by the pressing member.

### CROSS-REFERENCE TO RELATED APPLICATIONS

The present application is a continuation of International Application No. PCT/JP2024/041207, filed on November 21, 2024, and based upon and claims the benefit of priority from Japanese Patent Application No. 2023-213084, filed on December 18, 2023, the entire contents of which are incorporated herein by reference.

### TECHNICAL FIELD

The disclosure relates to a harness heat dissipation structure.

### BACKGROUND

JP 2020-21556 A discloses a technique relating to a wire harness that is used in a vehicle such as an electric vehicle or a plug-in hybrid vehicle and that includes electric wires for electrically connecting a high-voltage battery and an electric device such as an inverter. The wire harness includes a plurality of electric wires, a pair of connectors attached to both end portions of the electric wires, a plurality of exterior members through which the plurality of electric wires are individually inserted, and a plurality of clamps. Each of the exterior members protects the electric wire from, for example, flying objects or water droplets. The plurality of exterior members are fixed to a vehicle body of the vehicle or the like by the clamps. With this configuration, heat generated in the electric wires can be transmitted to the vehicle body having a large surface area via the exterior members and the clamps.

### SUMMARY OF THE INVENTION

In a vehicle, with the electrification of the vehicle, a larger current flows through a wire harness. With this increase in current, it is necessary to take measures against Joule heat generated particularly in an electric wire of the wire harness. The wire harness is fixed to a vehicle body for the purpose of heat dissipation. However, in such a case, heat dissipation based on thermal conduction from the electric wire of the wire harness to the vehicle body may be insufficient because the vehicle body is generally formed of an iron plate or a steel plate and thus has a relatively small heat capacity.

The disclosure has been made in view of such problems in the related art. Further, an object of the disclosure is to provide a harness heat dissipation structure capable of efficiently dissipating heat generated in an electric wire of a wire harness.

A harness heat dissipation structure according to an aspect of the disclosure includes a wire harness that is routed on a vehicle body of a vehicle, and a pressing member that presses the wire harness against the vehicle body, wherein the wire harness includes an electric wire including a conductor core wire having electric conductivity and a covering insulator covering the conductor core wire, the electric wire includes a flat portion having a flat cross-sectional shape in a direction orthogonal to a routing direction of the wire harness, and the vehicle body includes a thick portion that is formed thicker than surrounding portions at a location where the pressing member is attached and where the flat portion of the electric wire of the wire harness is pressed by the pressing member.

According to the disclosure, it is possible to provide a harness heat dissipation structure capable of efficiently dissipating heat generated in an electric wire of a wire harness.

### BRIEF DESCRIPTION OF DRAWINGS

FIG. 1 is a diagram illustrating a schematic configuration of a high-voltage wiring line of an electric vehicle to which the present embodiment is applied.

FIG. 2 is a schematic perspective view illustrating an example of a harness heat dissipation structure according to the present embodiment.

FIG. 3 is a schematic cross-sectional view illustrating an example of the heat dissipation structure according to the present embodiment.

FIG. 4 is a schematic perspective view illustrating an example of an electric wire of a wire harness.

FIG. 5 is a cross-sectional view taken along the line A-A of FIG. 4.

FIG. 6 is a cross-sectional view taken along the line B-B of FIG. 4.

FIG. 7 is a schematic cross-sectional view illustrating a harness heat dissipation structure according to another embodiment.

### DETAILED DESCRIPTION OF THE INVENTION

With reference to the drawings, a harness heat dissipation structure according to the present embodiment is described below in detail. Note that the dimensional ratios in the drawings are exaggerated for explanatory purposes, and may differ from the actual ratios.

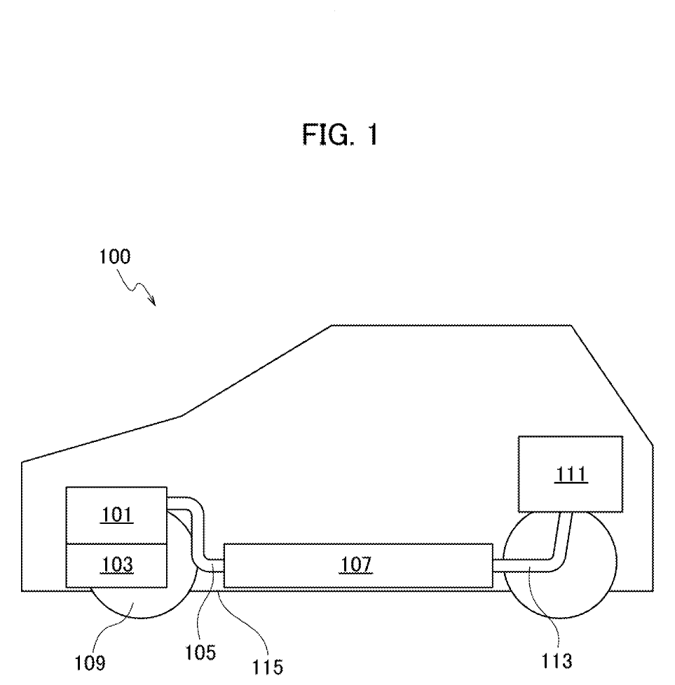

A harness heat dissipation structure 1 according to the present embodiment is applicable to a high-voltage wiring line of an electric vehicle or the like as illustrated in FIG. 1.

As illustrated in FIG. 1, in a vehicle 100, for example, an inverter 101 and a motor 103 serving as load units are arranged on a front side in a vehicle front-rear direction. The inverter 101 is electrically connected to a high-voltage battery 107 via a front-side high-voltage wiring line 105, and converts DC power supplied from the high-voltage battery 107 via the front-side high-voltage wiring line 105 into AC power. Further, the inverter 101 supplies the converted AC power to the motor 103. The motor 103 is driven by the power supplied from the inverter 101, and rotates front wheels 109 via a drive shaft or the like of the vehicle 100.

Further, in the vehicle 100, for example, a charging port 111 is arranged on a rear side in the vehicle front-rear direction. The charging port 111 includes a charging inlet to which an external charging device (omitted in illustration) serving as a charger is connected. The charging port 111 is electrically connected to the high-voltage battery 107 via a rear-side high-voltage wiring 113, and supplies power supplied from the external charging device via the rear-side high-voltage wiring line 113 to the high-voltage battery 107.

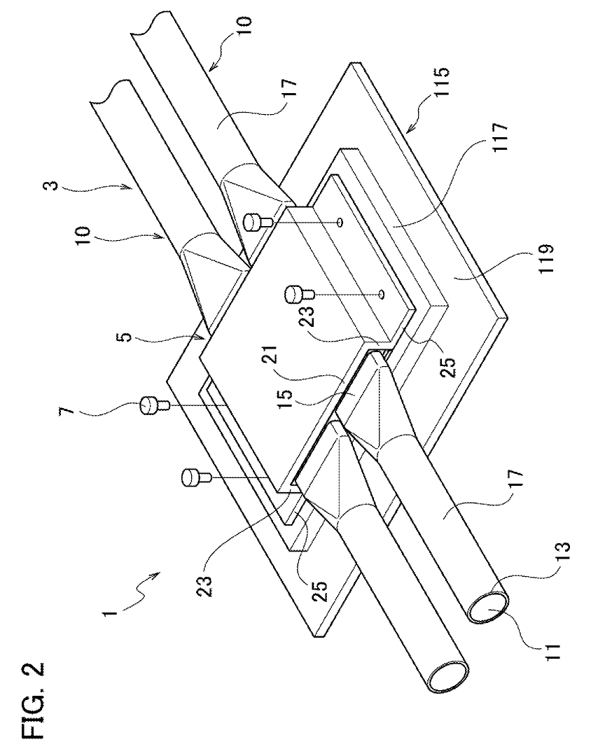

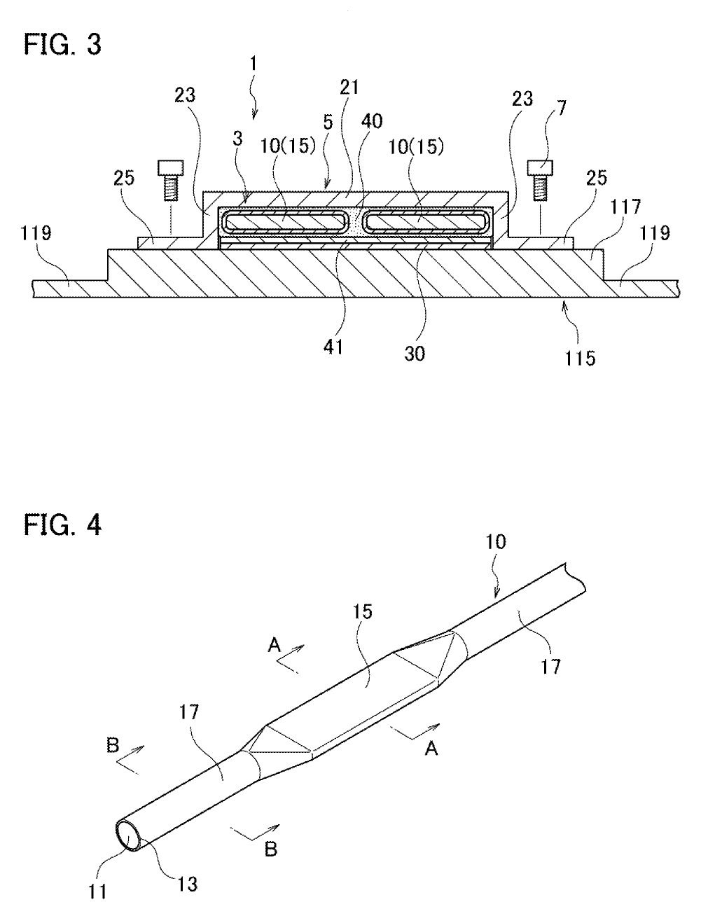

As illustrated in FIG. 2 and FIG. 3, the harness heat dissipation structure 1 according to the present embodiment includes a wire harness 3 and a pressing member 5.

The wire harness 3 is routed on a body panel 115 (see FIG. 1) forming a part of a vehicle body of the vehicle 100. The wire harness 3 includes an electric wire 10 including a conductor core wire 11 having electric conductivity and a covering insulator 13 covering the conductor core wire 11, and the conductor core wire 11 of the electric wire 10 is formed of a metal material such as copper or aluminum. The wire harness 3 includes a plurality of (in the present embodiment, two) electric wires 10. However, the number of electric wires 10 is not limited thereto, and the wire harness 3 may include a single (one) electric wire 10.

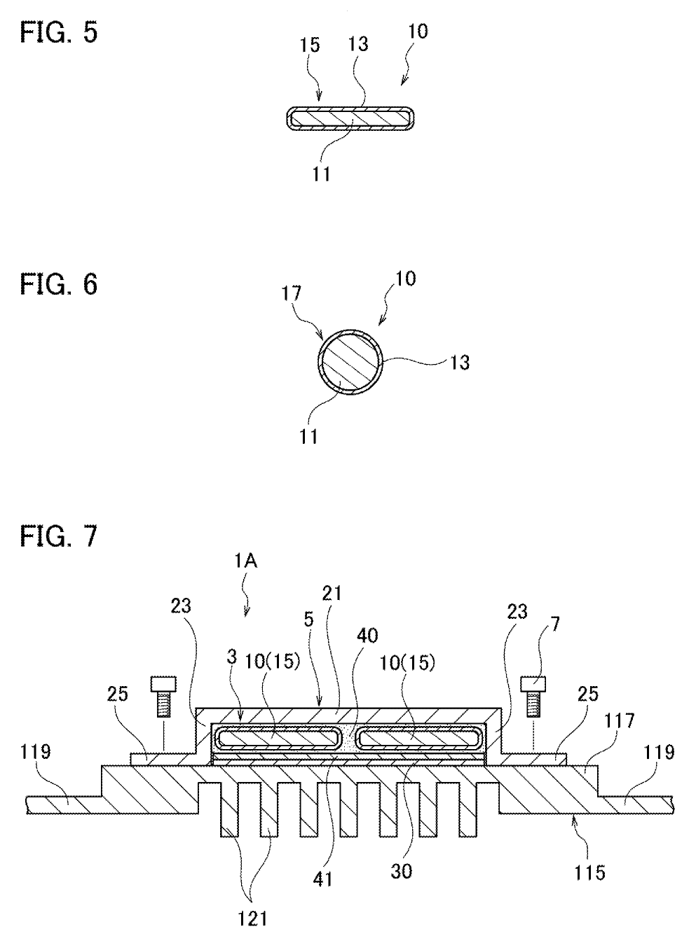

As illustrated in FIG. 4 to FIG. 6, the electric wire 10 includes a flat portion 15 having a flat cross-sectional shape in a direction orthogonal to a routing direction of the wire harness 3. In the present embodiment, a portion of the electric wire 10 other than the flat portion 15 is formed as a circular portion 17 having a circular cross-sectional shape in the direction orthogonal to the routing direction of the wire harness 3. In other words, in the present embodiment, the part of the wire harness 3 that is pressed against a thick portion 117 of the body panel 115, which is described later, is flattened to partially form the flat portion 15. However, the flat portion 15 is not limited thereto, and the flat portion 15 may be formed entirely at the wire harness 3 similarly to, for example, a flat cable.

As illustrated in FIG. 2 and FIG. 3, in the present embodiment, the electric wire 10 is arranged so that an upper surface and a lower surface thereof are substantially parallel to an upper surface of the body panel 115. Thus, the upper surface of the electric wire 10 faces an upper surface portion 21 of the pressing member 5, which is described later, and the lower surface of the electric wire 10 faces the thick portion 117 of the body panel 115.

The pressing member 5 is used to press the wire harness 3 against the body panel 115. The pressing member 5 may be formed of a synthetic resin material, or may be formed of a metal material. In the present embodiment, the pressing member 5 includes the upper surface portion 21 that extends along a direction intersecting with the routing direction of the wire harness 3, and a pair of side surface portions 23 and 23 that extend from both end portions of the upper surface portion 21 in an extending direction thereof toward the thick portion 117 of the body panel 115. Further, the pressing member 5 further includes a pair of flange portions 25 and 25 that extend from lower end portions of the side surface portions 23 in directions away from each other and are coupled to the thick portion 117 by a coupling member such as a bolt 7. In this manner, the pressing member 5 is formed to have a hat-like cross-sectional shape.

The flat portion 15 of the electric wire 10 that is pressed against the body panel 115 is arranged in a space surrounded by the upper surface portion 21 and the pair of side surface portions 23 and 23 of the pressing member 5 and the thick portion 117 of the body panel 115.

Further, at an outer periphery of the flat portion 15 of the electric wire 10, a thermally conductive member 40 having thermal conductivity is arranged so as to fill the periphery of the flat portion 15 and efficiently transmit heat generated in the flat portion 15 to the thick portion 117 of the body panel 115. The thermally conductive member 40 is formed of a thermal paste, a thermally conductive resin, or the like.

Further, at the pressing member 5, a metal plate 41 is arranged so as to accommodate and hold the flat portion 15 of the electric wire 10, which is covered by the thermally conductive member 40, in the above-mentioned space in the pressing member 5.

Further, a heat dissipation sheet 30 as a heat dissipation member having thermal conductivity is arranged between the flat portion 15 of the electric wire 10 and the thick portion 117 of the body panel 115 so that heat generated in the flat portion 15 of the electric wire 10 is efficiently transmitted to the thick portion 117 of the body panel 115. The heat dissipation sheet 30 is also referred to as a thermally conductive sheet, and is arranged in close contact with the metal plate 41 and the thick portion 117 of the body panel 115.

The wire harness 3 and the pressing member 5 are arranged on a vehicle cabin inner side (a floor upper side) of the body panel 115.

The body panel 115 includes the thick portion 117 that is formed thicker than surrounding portions at a location where the pressing member 5 is attached and where the flat portion 15 of the electric wire 10 of the wire harness 3 is pressed by the pressing member 5. A general portion 119 that is thinner than the thick portion 117 is formed around the thick portion 117 of the body panel 115. The thick portion 117 is formed so as to protrude toward the vehicle cabin inner side of the body panel 115. A metal plate forming a part of the thick portion 117 may be attached by welding or the like in addition to the body panel 115 formed of an iron plate or a steel plate. When the body panel 115 is manufactured by casting, the thick portion 117 may be integrally molded with the body panel 115 during casting. In other words, the thick portion 117 may be formed integrally with the body panel 115, or may be formed as a separate body different from the body panel 115 and attached to the body panel 115.

In this manner, the harness heat dissipation structure 1 according to an aspect of the present embodiment includes the wire harness 3 that is routed on the vehicle body (the body panel 115) of the vehicle 100, and the pressing member 5 that presses the wire harness 3 against the vehicle body (the body panel 115). The wire harness 3 includes the electric wire 10 including the conductor core wire 11 having electric conductivity and the covering insulator 13 covering the conductor core wire 11, and the electric wire 10 includes the flat portion 15 having a flat cross-sectional shape in the direction orthogonal to the routing direction of the wire harness 3. The vehicle body (the body panel 115) includes the thick portion 117 that is formed thicker than the surrounding portions at the location where the pressing member 5 is attached and where the flat portion 15 of the electric wire 10 of the wire harness 3 is pressed by the pressing member 5.

The pressing member 5 is used to press the electric wire 10 against the body panel 115. With this, Joule heat generated in the electric wire 10 can be transmitted to the body panel 115 and dissipated, and a temperature rise at the wire harness 3 can be suppressed. Thus, an increase in size of the components (particularly, the conductor core wire 11) forming the wire harness 3 for suppressing heat generation in the wire harness 3 can be avoided, and weight reduction of the wire harness 3 and reduction of manufacturing cost can be achieved.

The electric wire 10 includes the flat portion 15, and the flat portion 15 is pressed against the body panel 115 by the pressing member 5. With this, a surface area contacting with the body panel 115 can be increased as compared to a general electric wire having a circular cross-sectional shape. Further, the flat portion 15 is pressed against the body panel 115 by the pressing member 5. With this, heat generated in the electric wire 10 can be transmitted sufficiently to the body panel 115, and a temperature rise at the wire harness 3 can be suppressed.

Further, at the location of the body panel 115 against which the electric wire 10 is pressed by the pressing member 5, the thick portion 117 is formed. With this, the heat capacity of the body panel 115 can be increased. Further, a temperature rise at the wire harness 3 can be suppressed, or a temperature rise can be delayed. Thus, an increase in size of the components (particularly, the conductor core wire 11) forming the wire harness 3 for suppressing heat generation in the wire harness 3 can be avoided, and weight reduction of the wire harness 3 and reduction of manufacturing cost can be achieved.

As described above, according to the present embodiment, it is possible to provide the harness heat dissipation structure 1 capable of efficiently dissipating heat generated in the electric wire 10 of the wire harness 3.

In the harness heat dissipation structure 1, the heat dissipation member (the heat dissipation sheet 30) having thermal conductivity may be arranged between the flat portion 15 of the electric wire 10 and the thick portion 117 of the vehicle body (the body panel 115).

The heat dissipation sheet 30 is arranged at a portion of the electric wire 10 that faces the body panel 115. With this, the gap between the electric wire 10 and the body panel 115 can be filled, and heat can be efficiently transmitted from the electric wire 10 to the body panel 115.

In the harness heat dissipation structure 1, at the outer periphery of the flat portion 15 of the electric wire 10, the thermally conductive member 40 having thermal conductivity may be arranged.

The thermally conductive member 40 fills the periphery of the flat portion 15 of the electric wire 10. With this, heat can be efficiently transmitted from the electric wire 10 to the body panel 115.

In the harness heat dissipation structure 1, the pressing member 5 may include the upper surface portion 21 that extend along the direction intersecting with the routing direction of the wire harness 3, and the pair of side surface portions 23 and 23 that extend from both the end portions of the upper surface portion 21 in the extending direction thereof toward the thick portion 117 of the vehicle body (the body panel 115). The pressing member 5 may further include the pair of flange portions 25 and 25 that extend from the lower end portions of the side surface portions 23 in the directions away from each other and are coupled to the thick portion 117, and thus may be formed to have a hat-like cross-sectional shape. the flat portion 15 of the electric wire 10 that is pressed against the vehicle body (the body panel 115) may be arranged in the space between the upper surface portion 21 and the pair of side surface portions 23 and 23 of the pressing member 5 and the thick portion 117 of the vehicle body (the body panel 115).

By using the pressing member 5 formed to have a hat-like cross-sectional shape, the electric wire 10 is pressed against the body panel 115. With this, heat generated in the electric wire 10 can be transmitted sufficiently to the body panel 115, and heat dissipation performance by the harness heat dissipation structure 1 can be improved.

### Other Embodiments

With reference to FIG. 7, a harness heat dissipation structure 1A according to other embodiments is described below. Note that components that are substantially the same as those of the harness heat dissipation structure 1 described above are denoted by the same reference symbols, and descriptions thereof are omitted.

As illustrated in FIG. 7, in the harness heat dissipation structure 1A, a plurality of heat dissipation fins 121 are formed at a location where the thick portion 117 of the body panel 115 is formed on a vehicle cabin outer side (a floor lower side). the shape and the attachment direction of the heat dissipation fin 121 may be set so that air heated by thermal conduction from the electric wire 10 is prevented from stagnating between the plurality of heat dissipation fins 121. A metal material forming the heat dissipation fin 121 may be attached by welding or the like in addition to the body panel 115 formed of an iron plate or a steel plate. When the body panel 115 is manufactured by casting, the heat dissipation fin 121 may be integrally molded with the body panel 115 during casting. In other words, the heat dissipation fin 121 may be formed integrally with the body panel 115, or may be formed as a separate body different from the body panel 115 and attached to the body panel 115.

As described above, in the harness heat dissipation structure 1A, the wire harness 3 and the pressing member 5 may be arranged on the cabin inner side (the floor upper side) of the vehicle body (the body panel 115). At a location where the thick portion 117 of the vehicle body (the body panel 115) is formed on the vehicle cabin outer side (the floor lower side), the heat dissipation fin 121 may be formed.

On the back surface of the attachment surface of the electric wire 10 of the body panel 115, the heat dissipation fin 121 is formed, and a portion (an area surface) of the body panel 115 that contacts with external air is increased. With this, heat dissipation performance by the harness heat dissipation structure 1 can be improved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A harness heat dissipation structure comprising:
a wire harness that is routed on a vehicle body of a vehicle; and
a pressing member that presses the wire harness against the vehicle body, wherein
the wire harness includes an electric wire including a conductor core wire having electric conductivity and a covering insulator covering the conductor core wire,
the electric wire includes a circular portion having a circular cross-sectional shape in a direction orthogonal to a routing direction of the wire harness, and a flat portion partially formed in the electric wire and having a flat cross-sectional shape in the direction orthogonal to the routing direction of the wire harness, and
the vehicle body includes a thick portion that is formed thicker than surrounding portions at a location where the pressing member is attached and where the flat portion of the electric wire of the wire harness is pressed by the pressing member.

2. The harness heat dissipation structure according to claim 1, wherein
a heat dissipation member having thermal conductivity is arranged between the flat portion of the electric wire and the thick portion of the vehicle body.

3. The harness heat dissipation structure according to claim 1, wherein
the wire harness and the pressing member are arranged on a vehicle cabin inner side of the vehicle body, and
a heat dissipation fin is formed on a vehicle cabin outer side of the vehicle body at a location where the thick portion is formed.

4. The harness heat dissipation structure according to claim 1, wherein
a thermally conductive member having thermal conductivity is arranged on an outer periphery of the flat portion of the electric wire.

5. The harness heat dissipation structure according to claim 1, wherein
the pressing member is formed to have a hat-like cross-sectional shape, and includes:
an upper surface portion that extends along a direction intersecting with the routing direction of the wire harness;
a pair of side surface portions that extend from both end portions of the upper surface portion in an extending direction thereof toward the thick portion of the vehicle body;
a pair of flange portions that extend from lower end portions of the side surface portions in directions away from each other and are coupled to the thick portion, and
the flat portion of the electric wire that is pressed against the vehicle body is arranged in a space surrounded by the upper surface portion and the pair of side surface portions of the pressing member and the thick portion of the vehicle body.
